(19) United States
(12) Patent Application Publication
(10) Pub. No.: US 2025/0159549 A1
(43) Pub. Date: May 15, 2025

(54) METHOD AND APPARATUS FOR CODE RATE MATCHING OF POLAR CODE IN WIRELESS COMMUNICATION SYSTEM

(71) Applicants: SAMSUNG ELECTRONICS CO., LTD., Suwon-si (KR); RESEARCH & BUSINESS FOUNDATION SUNGKYUNKWAN UNIVERSITY, Suwon-si (KR)

(72) Inventors: Donghun LEE, Suwon-si (KR); Sanghyo KIM, Suwon-si (KR); Min JANG, Suwon-si (KR); Hyosang JU, Suwon-si (KR); Donghwa HAN, Suwon-si (KR); Jisang PARK, Suwon-si (KR)

(21) Appl. No.: 18/942,172

(22) Filed: Nov. 8, 2024

(30) Foreign Application Priority Data
Nov. 10, 2023 (KR) 10-2023-0155389

(51) Int. Cl. H04W 28/06; H04L 1/00

(52) U.S. Cl. CPC H04W 28/06; H04L 1/0007; H04L 1/0041; H04L 1/0057; H04L 1/0068

(57) ABSTRACT

The present disclosure relates to a 5G or a 6G communication system for supporting higher data rates beyond a 4G communication system such as LTE. The disclosure provides a method and an apparatus for selecting bits to be adaptively extra-frozen according to a message length to use a polar code in a wireless communication system.

### CROSS-REFERENCE TO RELATED APPLICATION

This application is based on and claims priority under 35 U.S.C. § 119 to Korean Patent Application No. 10-2023-0155389, filed on Nov. 10, 2023, in the Korean Intellectual Property Office, the disclosure of which is herein incorporated by reference in its entirety.

### BACKGROUND

### 1. Field

The disclosure relates to a communication method and apparatus using a polar code in a wireless communication system.

### 2. Description of Related Art

Considering the development of wireless communication from generation to generation, the technologies have been developed mainly for services targeting humans, such as voice calls, multimedia services, and data services. Following the commercialization of 5G (5th-generation) communication systems, it is expected that the number of connected devices will exponentially grow. Increasingly, these will be connected to communication networks. Examples of connected things may include vehicles, robots, drones, home appliances, displays, smart sensors connected to various infrastructures, construction machines, and factory equipment. Mobile devices are expected to evolve in various form-factors, such as augmented reality glasses, virtual reality headsets, and hologram devices. In order to provide various services by connecting hundreds of billions of devices and things in the 6G (6th-generation) era, there have been ongoing efforts to develop improved 6G communication systems. For these reasons, 6G communication systems are referred to as beyond-5G systems.

6G communication systems, which are expected to be commercialized around 2030, will have a peak data rate of tera (1,000 giga)-level bps and a radio latency less than 100 sec, and thus will be 50 times as fast as 5G communication systems and have the 1/10 radio latency thereof.

In order to accomplish such a high data rate and an ultra-low latency, it has been considered to implement 6G communication systems in a terahertz band (for example, 95 GHz to 3THz bands). It is expected that, due to severer path loss and atmospheric absorption in the terahertz bands than those in mmWave bands introduced in 5G, technologies capable of securing the signal transmission distance (that is, coverage) will become more crucial. It is necessary to develop, as major technologies for securing the coverage, radio frequency (RF) elements, antennas, novel waveforms having a better coverage than orthogonal frequency division multiplexing (OFDM), beamforming and massive multiple input multiple output (MIMO), full dimensional MIMO (FD-MIMO), array antennas, and multiantenna transmission technologies such as large-scale antennas. In addition, there has been ongoing discussion on new technologies for improving the coverage of terahertz-band signals, such as metamaterial-based lenses and antennas, orbital angular momentum (OAM), and reconfigurable intelligent surface (RIS).

Moreover, in order to improve the spectral efficiency and the overall network performances, the following technologies have been developed for 6G communication systems: a full-duplex technology for enabling an uplink transmission and a downlink transmission to simultaneously use the same frequency resource at the same time; a network technology for utilizing satellites, high-altitude platform stations (HAPS), and the like in an integrated manner; an improved network structure for supporting mobile base stations and the like and enabling network operation optimization and automation and the like; a dynamic spectrum sharing technology via collison avoidance based on a prediction of spectrum usage; an use of artificial intelligence (AI) in wireless communication for improvement of overall network operation by utilizing AI from a designing phase for developing 6G and internalizing end-to-end AI support functions; and a next-generation distributed computing technology for overcoming the limit of UE computing ability through reachable super-high-performance communication and computing resources (such as mobile edge computing (MEC), clouds, and the like) over the network. In addition, through designing new protocols to be used in 6G communication systems, developing mechanisms for implementing a hardware-based security environment and safe use of data, and developing technologies for maintaining privacy, attempts to strengthen the connectivity between devices, optimize the network, promote softwarization of network entities, and increase the openness of wireless communications are continuing.

It is expected that research and development of 6G communication systems in hyper-connectivity, including person to machine (P2M) as well as machine to machine (M2M), will allow the next hyper-connected experience. Particularly, it is expected that services such as truly immersive extended reality (XR), high-fidelity mobile hologram, and digital replica could be provided through 6G communication systems. In addition, services such as remote surgery for security and reliability enhancement, industrial automation, and emergency response will be provided through the 6G communication system such that the technologies could be applied in various fields such as industry, medical care, automobiles, and home appliances.

Channel coding is a technology that transmits a message with high reliability by using redundancy bits to transmit data, and the use of an error correction code is necessary for the technology. Claude Shannon defined a maximum amount of information transmission that can be used for reliability communication as “channel capacity,” and since then research on many error correction codes for accessing the channel capability of Shannon has been made. Starting with classic codes such as Hamming, Bose-Chaudhuri-Hocquenghem (BCH), and Reed-Solomon (RS) codes, various modern codes such as turbo codes, low-density parity-check (LDPC) codes, and polar codes have been newly proposed, and the LDPC code is known as a representative channel capacity-approaching code.

Among then, the polar code is an error correction code first proposed by Arikan in 2009 and corresponds to the first code that was theoretically proven to asymptotically achieve channel capacity with low decoding complexity as the code length increases in various types of binary-input discrete memoryless channels (BI-DMC). When the proposed successive cancellation (SC) decoding is performed, there is no advantage in terms of decoding performance compared to the existing LDPC code or the turbo code, but the decoding performance is greatly improved when SC-list (SCL) decoding and SCI decoding using a cyclic redundancy check (CRC) code/parity-check (PC) code are used. Particularly, through the 3^{rd} generation partnership project (3GPP) 5G standardization process, excellent performance was secured by simultaneously utilizing the CRC code and the PC code, and based on this, they were adopted as error correction codes for the ultra-wideband communication (enhanced mobile broadband (eMBB)) control channel. Furthermore, the polar code is considered as a channel code candidate for beyond 5G (B5G) and 6G communication based on strong decoding performance at short lengths.

Rate-matching technologies such as puncturing, shortening, and repletion are considered for polar code transmission of various code lengths. At this time, in the case of a punctured polar code, information bits are generated for which the capacity of a split-bit-channel becomes 0 due to puncturing bits, which are called incapable bits. In addition, bits that have relatively greatly decreases in reliability are generated. In 5G-NR, performance degradation is prevented by including the bits in a frozen bit set through an extra-freezing (EF) method.

### SUMMARY

The disclosure provides a method and an apparatus for selecting bits to be adaptively extra-frozen according to a message length to use a polar code in a wireless communication system.

According to an embodiment of the disclosure, a method of encoding a channel in a wireless communication system includes determining a length of a mother code, based on a length of at least one information bit to be transmitted and a target code rate, determining at least one frozen bit not to transmit information among first bits included in an input source vector corresponding to the mother code, based on the length of the at least one information bit, allocating the at least one information bit to at least one second bit except for the determined at least one frozen bit among the first bits included in the input source vector, and generating a codeword by encoding, into a predetermined polar code, the input source vector to which the at least one information bit is allocated.

An apparatus for encoding a channel in a wireless communication system includes a transceiver and at least one processor, wherein the at least one processor is configured to determine a length of a mother code, based on a length of at least one information bit to be transmitted and a target code rate, determine at least one frozen bit not to transmit information among first bits included in an input source vector corresponding to the mother code, based on the length of the at least one information bit, allocate the at least one information bit to at least one second bit except for the determined at least one frozen bit among the first bits included in the input source vector, and generate a codeword by encoding, into a predetermined polar code, the input source vector to which the at least one information bit is allocated.

The disclosure provides a rate-matching method and apparatus of polar codes, thereby improving the system performance of the existing polar codes.

As the disclosure provides a rate-matching method and apparatus of polar codes, a performance gain is particularly significant in a low-code rate area, and thus it is expected to be effective mainly in a control channel in which data transmission at a low-code rate is considered.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non−transitory” computer readable medium excludes wired, wireless, optical, or other communication links that transport transitory electrical or other signals. A non−transitory computer readable medium includes media where data can be permanently stored and media where data can be stored and later overwritten, such as a rewritable optical disc or an erasable memory device.

Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

The above and other aspects, features, and advantages of the disclosure will be more apparent from the following detailed description taken in conjunction with the accompanying drawings, in which:

FIG. 1 illustrates a channel synthesis and channel separation process for the polar code according to various embodiments of the present disclosure;

FIG. 2 illustrates an encoding process of the polar code according to various embodiments of the present disclosure;

FIG. 3 illustrates an example of puncturing of bits in encoding of the polar code according to various embodiments of the present disclosure;

FIG. 4 illustrates a sequence in which bit indexes of the polar code are arranged in the ascending order of reliability according to various embodiments of the present disclosure;

FIG. 5 illustrates an example of a split channel allocation method for a UCI message length according to various embodiments of the present disclosure;

FIG. 6A illustrates an example of allocation of split channels of the polar code according to various embodiments of the present disclosure;

FIG. 6B illustrates a channel capacity degradation ratio for a reliable index according to the number (U) of punctured bits in order to analyze the cause of the performance of extra-freezing according to various embodiments of the present disclosure;

FIG. 7 illustrates a channel capacity degradation ratio for a reliability index according to the number (U) of punctured bits according to various embodiments of the present disclosure;

FIG. 8A illustrates a BER under density evolution according to a reliability index according to various embodiments of the present disclosure;

FIG. 8B illustrates a BER under density evolution according to a reliability index according to various embodiments of the present disclosure;

FIG. 9 illustrates comparison between sizes of sets of EF bits according to K (a sum of the number of message bits and the number of CRC bits) for various punctured polar codes according to various embodiments of the present disclosure;

FIG. 10 illustrates bit indexes that additionally extra-frozen for each mother code length when bits of the polar codes are punctured according to various embodiments of the present disclosure;

FIG. 11 illustrates a split channel allocation method for the EF set when light puncturing is applied according to various embodiments of the present disclosure;

FIG. 12 illustrates a split channel allocation method for the EF set when heavy puncturing is applied according to various embodiments of the present disclosure;

FIG. 13 illustrates sizes of sets of extra-freezing bits in puncturing of bits of the polar codes according to various embodiments of the present disclosure; and

FIG. 14 illustrates a structure of an encoding device according to various embodiments of the present disclosure.

### DETAILED DESCRIPTION

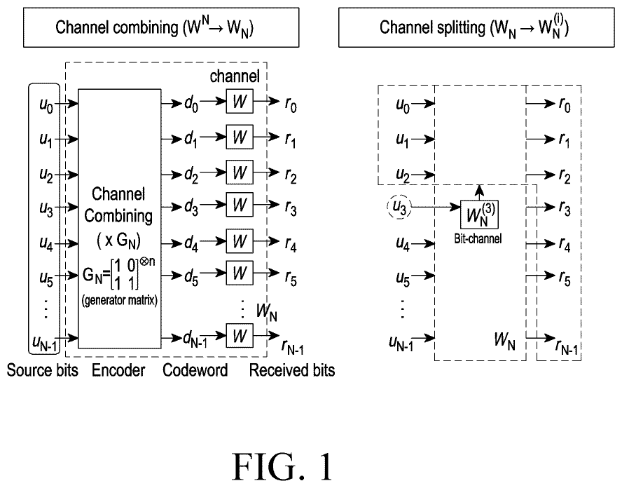

FIGS. 1 through 14, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

Hereinafter, the operation principle of the disclosure will be described in detail in conjunction with the accompanying drawings. In describing the disclosure below, a detailed description of known functions or configurations incorporated herein will be omitted when it is determined that the description may make the subject matter of the disclosure unnecessarily unclear. The terms which will be described below are terms defined in consideration of the functions in the disclosure, and may be different according to users, intentions of the users, or customs. Therefore, the definitions of the terms should be made based on the contents throughout the specification.

For the same reason, in the accompanying drawings, some elements may be exaggerated, omitted, or schematically illustrated. Furthermore, the size of each element does not completely reflect the actual size. In the respective drawings, the same or corresponding elements are assigned the same reference numerals.

The advantages and features of the disclosure and ways to achieve them will be apparent by making reference to embodiments as described below in detail in conjunction with the accompanying drawings. However, the disclosure is not limited to the embodiments set forth below, but may be implemented in various different forms. Various embodiments are provided to completely disclose the disclosure and inform those skilled in the art of the scope of the disclosure, and the disclosure is defined only by the scope of the appended claims. Throughout the specification, the same or like reference signs indicate the same or like elements.

Herein, it will be understood that each block of the flowchart illustrations, and combinations of blocks in the flowchart illustrations, can be implemented by computer program instructions. These computer program instructions can be provided to a processor of a general-purpose computer, special purpose computer, or other programmable data processing apparatus to produce a machine, such that the instructions, which execute via the processor of the computer or other programmable data processing apparatus, create means for implementing the functions specified in the flowchart block or blocks. These computer program instructions may also be stored in a computer usable or computer-readable memory that can direct a computer or other programmable data processing apparatus to function in a particular manner, such that the instructions stored in the computer usable or computer-readable memory produce an article of manufacture including instruction means that implement the function specified in the flowchart block or blocks. The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart block or blocks.

Furthermore, each block in the flowchart illustrations may represent a module, segment, or portion of code, which includes one or more executable instructions for implementing the specified logical function(s). It should also be noted that in some alternative implementations, the functions noted in the blocks may occur out of the order. For example, two blocks shown in succession may in fact be executed substantially concurrently or the blocks may sometimes be executed in the reverse order, depending upon the functionality involved.

As used in various embodiments of the disclosure, the term “unit” refers to a software element or a hardware element, and the “unit” performs certain functions. However, the “unit” does not always have a meaning limited to software or hardware. The “unit” may be constructed either to be stored in an addressable storage medium or to execute one or more processors. Therefore, the “unit” includes, for example, software elements, object-oriented software elements, class elements or task elements, processes, functions, properties, procedures, sub-routines, segments of a program code, drivers, firmware, micro-codes, circuits, data, database, data structures, tables, arrays, and parameters. The elements and functions provided by the “unit” may be either combined into a smaller number of elements, or a “unit,” or divided into a larger number of elements, or a “unit.” Moreover, the elements and “units” may be implemented to reproduce one or more CPUs within a device or a security multimedia card. Furthermore, the “unit” in various embodiments of the disclosure may include one or more processors.

As used herein, each of such phrases as “A and/or B,” “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. Such terms as “a first,” “a second,” “the first,” and “the second” may be used to simply distinguish a corresponding element from another, and does not limit the elements in other aspect (e.g., importance or order).

In the disclosure, a user equipment (UE) may be referred to as a terminal, a mobile station (MS), a cellular phone, a smartphone, a computer, or various types of electronic devices capable of performing communication functions. In the following description, a base station is an entity that allocates resources to terminals, and may be at least one of a Node B, an eNode B (eNB), a gNode B (gNB), a wireless access unit, a base station controller, and a node on a network.

Furthermore, the embodiments of the disclosure as described below may also be applied to other communication systems having similar technical backgrounds or channel types to the embodiments of the disclosure. In addition, based on determinations by those skilled in the art, various embodiments of the disclosure may also be applied to other communication systems through some modifications without significantly departing from the scope of the disclosure.

In the detailed description of various embodiments of the disclosure, a communication system may use a wireless communication system, and may use, for example, a 5G communication system on the 5G communication standard (new RAN (NR)) proposed by the 3rd generation partnership project long term evolution (3GPP LTE) that is a wireless communication standardization group. In addition, based on determinations by those skilled in the art, the disclosure may be applied to other communication systems having similar backgrounds or channel types through some modifications without significantly departing from the scope of the disclosure. In the following description, some of terms and names defined in the 3GPP standards may be used for the sake of descriptive convenience. However, the disclosure is not limited by these terms and names, and may be applied in the same way to systems that conform other standards.

In order to help understanding of embodiments of the disclosure, the polar code is first described.

FIG. 1 illustrates a channel combining and channel splitting process for the polar code according to various embodiments of the present disclosure.

Polar codes are codes that theoretically achieve channel capacity, and obtain polarized channels through channel combining and channel splitting, select high-quality channels suitable for communication, and transmit data. Referring to FIG. 1, a vector u (or a source vector) has both information bits and frozen bits, and a dimension thereof is N. The information bit has one binary value between {0, 1}, and the frozen bit is generally frozen to 0. Thereafter, a codeword vector d is generated through the product with a generator matrix

$${G}_{N} = {G}_{2}^{⊗ n} ( {G}_{2} = [ \begin{matrix}1 & 0 \\ 1 & 1\end{matrix} ] ) ( d = u \cdot {G}_{N} ) .$$

The codeword vector is modulated, passes through an independent and identically distributed (i.i.d) channel in units of symbols, and becomes a reception signal vector r. At this time, one large combined channel W_{N} that connects the vector u and the reception signal vector r may be defined, which is called channel combining. Channel splitting refers to a process for obtaining virtual split channels W_{N}⁽ⁱ⁾ (i being split channel index) experienced by respective source bits from W_{N}. The split channel is defined by a transition probability W_{N}⁽ⁱ⁾(r, u₀ⁱ⁻¹|uᵢ) having uᵢ as an input and r, u₀ⁱ⁻¹(=u₀, u₁, . . . , uᵢ₋₁) as an output. As known from a transition probability equation, the reliability and capacity of split channels are sequentially evaluated based on the assumption that results of all source bits u₀ⁱ⁻¹ that have been previously estimated are correct (that is genie-aided and the reliability and capacity of each split channel are evaluated) (genie-aided SC decoding).

At this time, indexes may be arranged in the order from the lowest-quality split channels to the highest-quality split channel, based on the reliability of W_{N}⁽ⁱ⁾, which is called a polar code sequence. Bits located ahead of the code sequence due to small W_{N}⁽ⁱ⁾ are transmitted with fixed values, and bits located behind the code sequence due to large W_{N}⁽ⁱ⁾ are used for data transmission. In order to design the code sequence, various methods such as a Bhattacharyya parameter update, density evolution, Gaussian approximation, and a polarization weight may be used.

Among them, the density evolution (DE) is representative. First, based on transmission of a zero-codeword (CW) (u=0), a probability density function (pdf) of a reception signal log-likelihood ratio (LLR) message obtained from the channel output is determined, and then the pdf of the LLR message in a phased polarization process is acquired and the LLR pdf of split channels of each source bit uᵢ is acquired. Accordingly, it is a method of evaluating the reliability and capacity of each split channel and designing the code by using the same.

That is, a bit error rate (BER) of each bit may be calculated based on the LLR pdf acquired by upgrade (VN operation) and downgrade (CN operation) of each bit through n=log₂ N polarization steps.

In 5G-NR, one code sequence is defined and used to reflect the fixed dominance relation between the bit channels in order to avoid the code design varying depending on the channel and to make the code design that is close to the optimal design for various code parameters and is fixed possible.

When data is transmitted to high-reliable split channels by the evaluation of the quality of polarized split channels through channel combining and splitting, a transmitted message is estimated through an appropriate decoding method based on a reception signal r=(r₀, r₁, . . . , r_{N-1}) acquired by passing through the channel.

In the decoding method, it is possible to significantly improve the error detection/correction capability of the code by using a cyclic redundancy check (CRC) code or a parity-check (PC) code together, and 5G-NR considers other concatenated codes according to the message length.

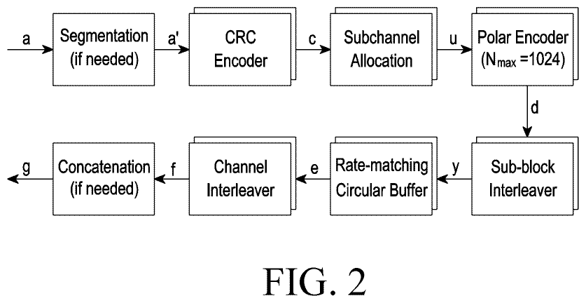

FIG. 2 illustrates an encoding process of the polar code according to various embodiments of the present disclosure.

FIG. 2 illustrates an encoding chain of a 5G polar code in system models considering 5G-NR encoding.

Referring to FIG. 2, the encoding chain of the 5G polar code may include the following operation:
\hat{1} Code block segmentation (Only uplink (conditionally));
\hat{2} Mother code configuration (both UL, DL);
\hat{3} CRC encoding (both UL, DL);
\hat{4} Input bits interleaver (only DL);
\hat{5} Subchannel allocation and PC bits calculation (both UL, DL);
\hat{6} Polar encoding (both UL, DL);
\hat{7} Sub-block interleaver (both UL, DL);
\hat{8} Rate-matching (both UL, DL); and
\hat{9} Channel interleaver (Only UL).

In FIG. 2, a vector a is a message vector having the size of A. The message vector may be segmented into two sub-message vectors according to a code parameter. In the case of segmentation, respective sub-message vectors a′ are independently encoded, concatenated before modulation, and transmitted. The segmented vector a′ having the length of A′ is concatenated with an L-bit CRC, and thus a vector c having the length of K=A′+L is generated. At this time, the mother code length N is determined by the target code rate R and the effective code length E, and locations of the information bit, the frozen bit, the parity bit, and the CRC bit within the source vector u having the length of N are determined. Thereafter, the vector u becomes the codeword d=u·G_{N} (″ being the inner product in [symbol] ₂), and the sub-block interleaver splits the codeword vector into 32 sub-blocks and then interleaves the same in units of blocks. The output sequence y having the length of N becomes the input of a circular buffer, and the circular buffer selects one mode that meets a condition from among three modes (puncturing, shortening, and repetition) and outputs a codeword e that matches the length E. For example, the puncturing is applied in the case of K/E≤7/16 and transmits only the last E bits of the circular buffer (first U=N−E bits are not transmitted), the shortening is used for K/E>7/16 and transmits first E bits (last U=N−E bits are not transmitted), and the repetition additionally transmits first E−N bits in the case of E>N. Thereafter, bits are rearranged once again through channel interleaving corresponding to bit unit interleaving, and the output g becomes the input of a modulator.

At this time, the vector g(g=f when there is no split) is binary data after the encoding process. The modulator considers binary phase shift keying (BPSK) modulation unless specifically mentioned, but the disclosure includes the application of high order modulation such as quadrature phase shift keying (QPSK) and quadrature amplitude modulation (QAM), and the used modulation methods are not limited thereto. A modulated vector x becomes the reception signal vector r by passing through the channel. The channel is basically assumed as an additive white Gaussian noise (AWGN) channel. However, without exclusion of the assumption of a fading channel, a superchannel for wideband modulation and demodulation such as orthogonal frequency division multiplexing (OFDM) may be included.

Hereinafter, the operation included in the encoding chain of the polar code is described in detail.
\textcircled{1} Code block segmentation (Only uplink (conditionally)).

The input is a vector a having the size of A, and the output is a vector a′ having the size of A′. In downlink (DL), segmentation is not performed. (I_{seg}=0 (inactivated)), in uplink (UL), segmentation is conditionally performed only for sufficiently long uplink control information (UCI) (I_{seg}=1 (activated) for UL (conditionally)). A condition equation of parameters A, E in which code block segmentation is performed is as shown in [Equation 1].

$$( A \geq 1013 ) or ( A \geq 360 and E \geq 1088 ) \qquad [ Equation l ]$$

In the segmentation step, the information block is segmented into two sub-blocks, an independent encoding process is performed for each sub-block, and then two vectors are concatenated before modulation. In an example of the disclosure, the case (A′=A) of a single block is mainly assumed.
\textcircled{2} Mother code configuration (both UL, DL)

Based on the transmission message length A′ (A′=A when there is no message segmentation and A′=┌A/2┐ when there is segmentation) and the target code rate, the actual transmission codeword length E=A/R is determined. At this time, the length E is adjusted to the mother code having the length of N=2ⁿ, based on a rate-matching technology such as puncturing, shortening, and repetition.^{T} may be expressed as shown in [Equation 2] below.

$$n = max ( min ( {n}_{1} , {n}_{2} , {n}_{max} ) , {n}_{min} ) \qquad [ Equation 2 ]$$

nₘₐₓ is 10 (UL), 9 (DL), and nₘᵢₙ is 5 (both UL, DL). Further, n₁=┌log₂ E┐, n₂=┌log₂(8K)┐(K=A+L; L being the number of CRC bits). However, in order to prevent the application of excessive puncturing or shortening, n₁=└log₂ E┘ is determined in the case of {log₂(E)}<0.17 ({x}=x−└x┘).

For example, in the case of a code of (E, A)=(70,30), ≈log₂(70)−└log₂(70)┘<<0.17, and thus n₁=6. When this is substituted into [Equation 2], n=max(min(6┌log₂(240)┐, 10), 5)=6. That is, the length of the mother code 2⁶=64. 58 bits from the mother polar code having the length of 128 are not punctured (or shortened), and 6 bits from the mother polar code having the length of 64 are repeatedly transmitted. If the length of the mother polar code is N>E, the mother code is punctured (or shortened) for transmission of the codeword having the length of E. The puncturing is performed when K/E≤≤7/16 and the shortening is performed when K/E>7/16.

For both the puncturing and the shortening, some of the codeword bits are not transmitted. At this time, a pattern of the bits to be not transmitted is determined by a sub-vector for an output vector of the sub-block interleaver. In the case of puncturing, there is no information on codeword bits that were not transmitted when a receiver performs decoding, and thus the LLR of the corresponding bits is configured as 0 and the decoding is performed. The trend of channel polarization is changed by the punctured bits, and becomes capacity-0 in the u domain, and thus bits meaningless to data transmission are generated. At this time, an index set of the punctured bits is a puncturing pattern, and an index set of source bits of capacity-0 is an incapable pattern. As described below, when the number of punctured bits is U, the puncturing pattern is a sub vector including first U bits of the output vector of the sub-block interleaver.

In 5G-NR, the bits are preferentially selected as frozen bits, and a set of the bits is frozen bits. For example, signal transmission through a binary erasure channel (BEC) of the polar code of [symbol] ₚ={1,3} having the length of 8 is assumed (that is, {ε₀, ε₁, ε₀, ε₁, ε₀, ε₀, ε₀, ε₀} where ε₀=0.5 and ε₁=1, an erasure probability (ε₁) of the channel corresponding to the punctured bits=1, and an erasure probability (ε₀) of the remaining channels is configured as 0.5). At this time, channel capacities of respective split channels are {0, 0.063, 0, 0.438, 0.141, 0.672, 0.703, 0.984}. Since channel capacities corresponding to u₀ and u₂ are 0, [symbol] ₚ={0,2} (in which case| [symbol] ₚ|=| [symbol] ₚ| or [symbol] ₚ≠ [symbol] ₚ). In general, | [symbol] ₚ|=| [symbol] ₚ| is always satisfied for a random puncturing pattern, and [symbol] ₚ= [symbol] ₚ is satisfied in the case of P determined by the sub-block interleaver of 5G-NR.

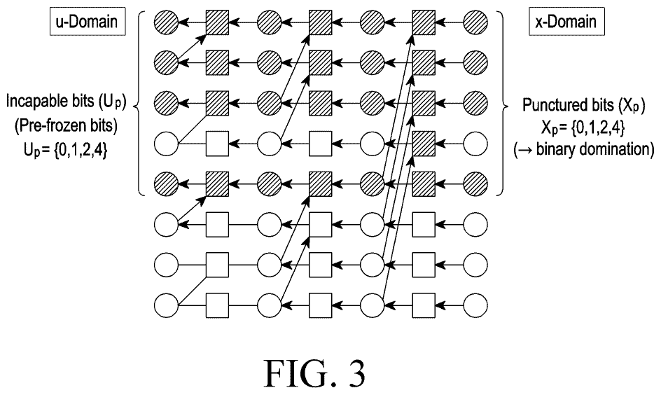

FIG. 3 illustrates an example of puncturing of bits in encoding of the polar code according to various embodiments of the present disclosure.

FIG. 3 shows the polar code encoding structure corresponding to (N, U)=(8, 4), [symbol] ₚ={0, 1, 2, 4}. A puncturing pattern ( [symbol] ₚ) defined in an x domain and an incapable pattern ( [symbol] ₚ) in a u domain are the same like [symbol] ₚ= [symbol] ₚ={0, 1, 2, 4}.

\textcircled{3} CRC encoding (both UL, DL)

The input is a vector A′ having the size of a′, and the output is a vector K(=A′+L) having the size of c. L is the length of the CRC code. CRC encoding may be performed in UL and DL, and uses different CRC parity lengths according to the message length (A). As an embodiment, the CRC encoding may be omitted during the procedure of FIG. 2. Specifically, the CRC is not used in very short UCI (that is, A≤11). A 6-bit CRC is used in short UCI (that is, 12≤A≤19), and a 11-bit CRC is used in medium-long UCI (that is, A≥20). The error detection capability is increased using a 24-bit CRC in DL. CRC polynomials used at this time are as shown in [Equation 3] below.

$${g}_{CRC 6} ( D ) = {D}^{6} + {D}^{5} + 1 \qquad [ Equation 3 ]$$

$${g}_{CRC 11} ( D ) = {D}^{11} + {D}^{10} + {D}^{9} + {D}^{5} + 1$$

$${g}_{CRC 24} ( D ) = {D}^{24} + {D}^{23} + {D}^{21} + {D}^{20} + {D}^{17} + {D}^{15} + {D}^{13} + {D}^{12} + {D}^{8} + {D}^{4} + {D}^{2} + D + 1$$

### \textcircled{4} Input Bits Interleaver (Only DL)

The input is a vector c having the length of K(=A′+L), and the output is a vector c′ having the length of K(=A′+L). CRC bits may be distributed through the bit interleaving, and early decoding failure is determined by some of the forward deployed CRC bits, and thus decoding complexity may be reduced. The interleaver is applied only to the DL (I_{IL}=1 for DL), and is not used for the UL. Unlike a base station having a high calculation processing capability in the case of UL, it is necessary to reduce complexity obtained by early decoding termination due to the distributed CRC in the DL because calculation throughput of mobile devices is low in the DL.

### \textcircled{5} Subchannel Allocation and PC Bits Calculation (Both UL, DL)

The input is a vector c (or c′) having the length of K, and the output is a vector u having the length of N. n_{PC} parity-check (PC) bits are inserted into K(=A+L) messages and CRC bits (K′=n_{PC}), and the remaining (N−K′) bits are frozen to 0. Specifically, in 5G-NR, a frozen bit set Q̅_{F}^{N} and an information set Q̅_{I}^{N} are determined based on a code sequence Q₀^{N}^{ₘₐₓ}⁻¹.

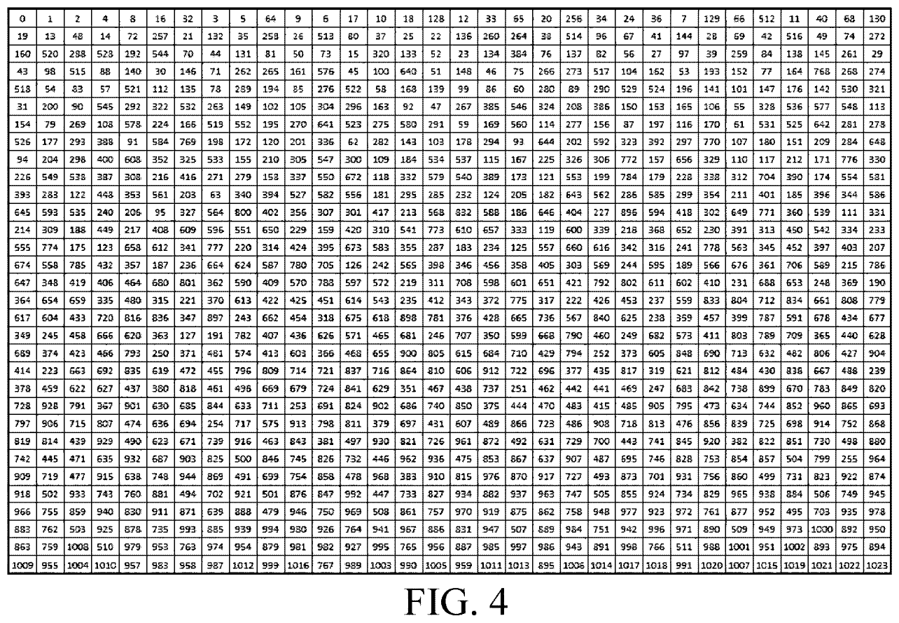

FIG. 4 illustrates a sequence in which bit indexes of the polar code are arranged in the ascending order of reliability according to various embodiments of the present disclosure. Specifically, the reliability of a split channel corresponding to a bit index located in the first row and the first column is the lowest, and the reliability of a split channel corresponding to a bit index located in the last row and the last column is the highest. Further, the reliability increases as going to the right, and the reliability of a bit having an index corresponding to the first column of an (i±1)^{th} row is higher than the reliability of a bit corresponding to an index corresponding to the last column of an i^{th} row.

FIG. 4 illustrates a code sequence

$${Q}_{0}^{{N}_{m ax} - 1} = \{ {Q}_{0}^{{N}_{m ax}} , {Q}_{1}^{{N}_{m ax}} , … , {Q}_{{N}_{m ax} - 1}^{{N}_{m ax}} \}$$

5G-NR corresponding to a polar code sequence Q₀¹⁰²³ that arranges bit indexes in the ascending order of reliability for the polar code having the length of Nₘₐₓ=1024, and 0≤Qᵢ^{N}^{ₘₐₓ}≤Nₘₐₓ−1 is a source bit index. It is a bit corresponding to Q₀¹⁰²⁴ on the left top and Q₁₀₂₃¹⁰²⁴ on the right bottom. At this time, the reliability of each bit satisfies

$$W ( {Q}_{0}^{{N}_{m ax}} ) < W ( {Q}_{1}^{{N}_{m ax}} ) < … < W ( {Q}_{{N}_{m ax} - 1}^{{N}_{m ax}} ) .$$

A code sequence Q₀^{N-}1 having the length of N(32≤N≤1024) is Q₀^{N-1}={Q₀^{N}, Q₀^{N}, . . . , Q_{N-1}^{N}}. Q₀^{N-1} is a sub-sequence of Q₀^{N}^{_{max−1}}, and corresponds to a sequence that sequentially extracts elements having indexes smaller than N from Q₀^{N}^{_{max−1}}. The elements within the sub-sequence satisfy the relation of W(Q₀^{N})<W(Q₁^{N})< . . . <W(Q_{N-1}^{N}). For example, a code sequence Q₀¹²⁷={Q₀¹²⁸, Q₁¹²⁸, . . . , Q₁₂₇¹²⁸, } of N=128 is a sequence that sequentially extracts bits having indexes smaller than 128 from Q₀¹⁰²³. Q₀²⁵⁵={Q₀²⁵⁶, Q₁²⁵⁶, . . . , Q₂₅₅²⁵⁶} is a sequence that sequentially extracts bits having indexes smaller than 256 from Q₀¹⁰²³. Q₀⁵¹¹={Q₀⁵¹², Q₁⁵¹², . . . , Q₅₁₁⁵¹²} is a sub-sequence that extracts elements having indexes smaller than 512 from Q₀¹⁰²³. First, summary of a method of determining Q̅_{F} ^{N} is described below.
1) Pre-freezing: S₁={J(γ), . . . , J(γ+U−1)} is a pre-freezing set and is preferentially included in a frozen bit set Q̅_{F}^{N}. J(·) is an output sequence by the sub-block interleaver, and γ=0 in puncturing and γ=E in shortening.
2) Extra-freezing: S₂={0, 1, . . . , T} is an extra-freezing set, and T is determined by [Equation 4] below and an extra-freezing process is performed only in puncturing. S₂=Ø in shortening.

$$T = \{ \begin{matrix}⌈ \frac{3 N}{4} - \frac{E}{2} ⌉ - 1 , & if E \geq \frac{3 N}{4} \\ ⌈ \frac{9 N}{16} - \frac{E}{4} ⌉ - 1 , & otherwise\end{matrix} \qquad [ Equation 4 ]$$

3) Reliability freezing: S₃=(Q₀^{N-1}\(S₁ ∪S₂)) [1: N−K′−|S₁ ∪S₂|] is a reliability freezing set.

Bits in the u domain of which capacities become 0 by bits punctured in the x domain are called incapable bits, and thus it is preferable to first freeze the bits. An index set of the bits is a pre-freezing set and is expressed as S₁. It is the same as the incapable pattern [symbol] ₚ in “\textcircled{2} mother code configuration (both UL, DL)” (S₁= [symbol] ₚ). Since the error always occurs even though data is transmitted to the bits, a value fixed to 0 is transmitted (not used for data transmission). Meanwhile, u bits that are not capacity-0 by the punctured bits but are relatively weaker are generated. For puncturing of the bits, all of the u bits having indexes equal to or smaller than T are additionally frozen according to the number of punctured bits. A configuration condition of the set S₂ is described below:
\textcircled{1} When E<3N/4, the EF set S₂ is S₂={0, 1, . . . , T} where

$$T = ⌈ \frac{9 N}{16} - \frac{E}{4} ⌉ - 1$$

(heavy puncturing); and
\textcircled{1} When E≥3N/4, the EF set S₂ is S₂={0, 1, . . . , Y} where

$$T = ⌈ \frac{3 N}{4} - \frac{E}{2} ⌉ - 1$$

(light puncturing).

S₁ and S₂ may or may not have the inclusion relationship according to a level of puncturing. For example, with respect to the size |S₁-S₂| of a difference set varying depending on the number U of punctured bits in the case of N=256, S₁⊂S₂ is always satisfied up to U=N/4 (light puncturing) but (heavy puncturing) S₁−S₂≠Ø when the number of punctured bits increases more than U. In a reliability freezing step, except for indexes of S₁ ∪S₂, the first (N−K′−|S₁∪S₂|) bits of Q₀^{N-1} are additionally frozen, and an index set thereof is 3. Accordingly, Q̅_{F}^{N}=S₁ ∪S₂ ∪S₃. After is designed through the three steps, the information bit, the CRC bit, and the parity-check (PC) bit are arranged in the remaining K′(=A+L+n_{PC}) to transmit data.

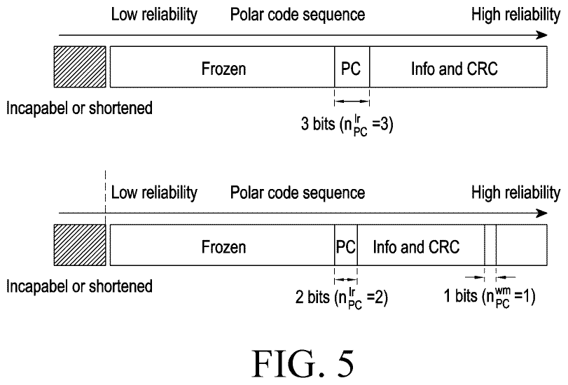

FIG. 5 illustrates an example of a split channel allocation method according to the uplink control information (UCI) message length.

Referring to FIG. 5, in 5G-NR, n_{PC}=3 bits are used only for the length of short uplink control information (UCI) (12≤A≤19) (n_{PC}=0 if A≥20), and the upper part of FIG. 5 illustrates the case of E−K+3≤192 in which case (n_{PC}^{lr}, n_{PC}^{wm})=(3,0). The lower part of FIG. 5 illustrates the case of E−K+3>192 in which case (n_{PC}^{lr}, n_{PC}^{wm})=(2,1).

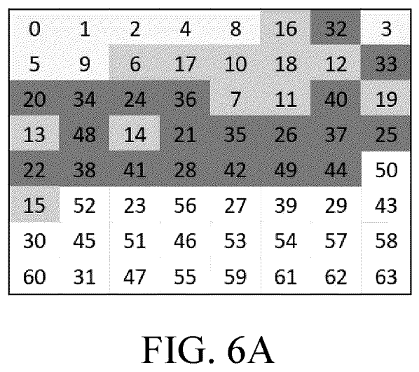

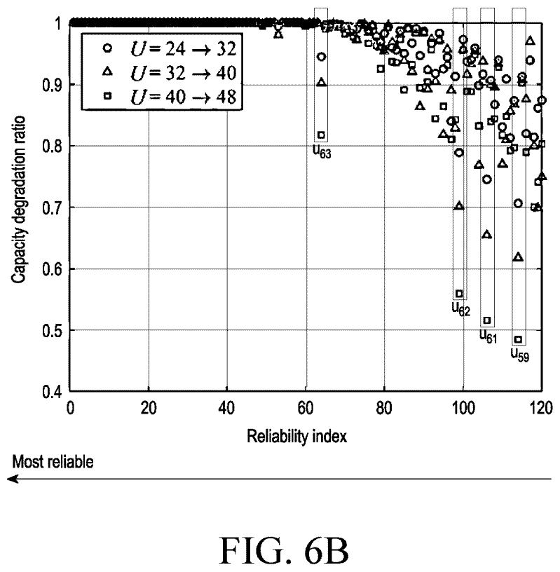

FIG. 6A illustrates an example of allocation of split channels of the polar code according to various embodiments of the present disclosure.

FIG. 6A shows an example of allocation of split channels of the polar code corresponding to (N, K′, U)=(64, 24, 8). A mother code sequence Q₀⁶³ corresponding to N=64 is a sub-sequence made by extracting elements equal to or smaller than 64 from Q₀¹⁰²³. First, since A≥20, n_{PC}=0. Further, since U=8, u bits of a pre-freezing set S₁={0, 1, 2, 3, 4, 5, 8, 9} that matches the puncturing pattern are frozen to 0. Subsequently, according to an extra-freezing rule, u bits (that is, S₂={0, 1, . . . , 19}) having an index of

$$\{ 0 , 1 , … , T \} ( T = ⌈ \frac{192}{4} - \frac{56}{2} ⌉ - 1 = 19 )$$

are additionally frozen. In case of this example, S₁ØS₂. Subsequently, the first (N−K′−|S₁ ∪S₂|)=20 bits of Q₀⁶³ are additionally frozen (reliability freezing; S₃={32, 33, 20, 34, 24, 36, 40, 48, 21, 35, 26, 37, 25, 22, 38, 41, 28, 42, 49, 44}). Data is carried on 24 bits except for Q̅_{F}⁶⁴=S₁ ∪S₂ ∪S₃ and transmitted. When extra-freezing is not performed, data is transmitted to u bits (that is, u₁₅) having an index of 15, and when the information set is reconfigured through extra-freezing, data is transmitted to u₅₀ rather than to u₁₅. That is, in this case, Q̅_{I}⁶⁴ is {50, 52, 23, 56, 27, 39, 29, 43, 30, 45, 51, 46, 53, 54, 57, 58, 60, 31, 47, 55, 59, 61, 62, 63}.

FIG. 6B illustrates a channel capacity degradation ratio for a reliability index according to the number (U) of punctured bits in order to analyze the cause of the performance of extra-freezing.

FIG. 6B shows capacity degradation ratios of bits according to an increase in the number of punctured bits in a binary erasure channel (BEC) having N=256 and an erasure probability of 0.5. The X axis indicates the reliability index (j ∈[0: N−1]). Specifically, for a sequence corresponding to the reverse order of the code sequence Q₀^{N-1}, a reliability index of the highest reliable bit is 0, and a reliability index of the lowest reliable bit is N−1. The Y axis indicates a ratio between the channel capacity in the case of U=p of the bit having the index of Q_{N-1-j}^{N} and the channel capacity in the case of U=p+8. Y has a value between 0 and 1, and a deterioration degree is larger as the value is closer to 0.

At this time, indexes of u bits corresponding to points highlighted in gray are 63, 62, 61, and 59. They always have indexes smaller than T (T=75, 79, 83, and 87 when U=24, 32, 40, and 48) obtained through [Equation 3] above and thus are extra-frozen. That is, in 5G-NR, performance deterioration of the bits having a relatively large channel capacity degradation ratio according to puncturing is prevented through extra-freezing.

The reason why extra-freezing is performed is described from a perspective of the density evolution. In the case of (N, U)=(128, 20), for an evolved (or polarized) BER for a u-bit index under an input SNR=−2 dB, the smaller the BER of uᵢ, the better the bit. In the case of (N, U)=(128, 20), T=41, and thus source bits having indexes S₂={0, 1, . . . , 41} are all extra-frozen. In this case, for the evolved BER for the u-bit index, bits having indexes S₂={0, 1, . . . , 41} generally have a higher BER compared to bits having indexes S₂^{c}={42, . . . , 127} and are weak at puncturing. In summary, bits weak at puncturing are extra-frozen from a perspective of the quality (channel capacity or BER) for each bit or row weight (or minimum distance of the code) of source bits in 5G-NR.

### \textcircled{6} Polar Encoding (Both UL, DL)

The input is a vector u having the length of N, and the output is a vector d having the length of N. The relation between the vectors u and d is defined by a generator matrix G_{N}, and

$$d = u \cdot {G}_{N} ( {G}_{N} = {G}_{2}^{⊗ n} , {G}_{2} = [ \begin{matrix}1 & 0 \\ 1 & 1\end{matrix} ] , n = {log}_{2} N ) .$$

### \textcircled{7} Sub-Block Interleaver (Both UL, DL)

The input is a vector d having the length of N, and the output is a vector y having the length of N. N encoded bits are interleaved in units of sub-blocks before rate-matching. Specifically, the vector is interleaved by [Equation 5] below after being segmented into B=N/32 sub-blocks (integer of B≥1 because Nₘᵢₙ=32). At this time, J(·) is a sub-block interleaver sequence, and the interleaver sequence is (0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31).

$$i = J ( j ) = B \cdot P ( ⌊ j / B ⌋ ) + q \qquad [ Equation 5 ]$$

$$( q = j mod B ( for all j ∈ [ 0 : N - 1 ] ) )$$

### \textcircled{8} Rate-Matching (Both UL, DL)

The input is a vector Y having the length of N, and the output is a vector e having the length of E(=N−U). The rate-matching is performed by the circular buffer and the rate-matching technologies are considered in 5G-NR. Since the bits to be transmitted are determined through rate-matching, the rate-matching is also called bit-selection, and one of the operations such as puncturing, shortening, and repetition is performed through bit-selection.
Puncturing: is applied when E≤N N and K/E≤7/16. The bits to be transmitted are determined by eᵢ=y_{i+U}(i ∈[0:E−1]), and first U=N−E bits of the vector y are not transmitted.
Shortening: is applied when E≤N and K/E≤7/16. The bits to be transmitted are determined by eᵢ=yᵢ(i ∈[0: E−1]), and last U=N−E bits of the vector y are not transmitted.
Repetition: is applied when E>N. Additionally transmitted bits are determined by eᵢ=y_{i mod N}(i ∈[0:E−1]).

### \textcircled{9} Channel Interleaver (Only UL)

The input is a vector e having the length of E, and the output is a vector f having the length of E. The vector e is interleaved in units of bits before modulation is performed and becomes the vector f. The channel interleaver has a right isosceles triangular structure. The interleaver is applied to improve the error rate performance of high order modulation (ex. 16QAM or 64QAM) and is used only for the UL.

For reference, the summary of values of all code parameters defined by the 5G UL is as shown in [Table 1] below.

TABLE 1

| | | A ≥ 20 | | | |
|---|---|---|---|---|---|
| | | | [symbol] ) | | |
| | | ( ) | (A < 360)∨ | | |
| | | (A ≥ 1013) ∨ | (A < | | |
| 5G-UL | | (A ≥ 360 ∧ G ≥ | 1013 ∧ | 12 ≤ A ≤ 19 | |
| (PUCCH, PUSCH) | | 1088) | G < 1088) | E − A ≤ 175 | E − A > 175 |
| Max. length | nₘₐₓ | 10 | | | |
| Input bit | I_{IL} | 0 | | | |
| interleaving flag | | | | | |
| Channel | I_{BIL} | 1 | | | |
| interleaving flag | | | | | |
| Segmentation flag | I_{seg} | 1 | 0 | | |
| Max payload length | Gₘₐₓ | 16384 | 8192 | | |
| Min payload length | Gₘᵢₙ | 31 | | 18 | |
| Max message length | Aₘₐₓ | 1706 | | | |
| Min message length | Aₘᵢₙ | 12 | | | |
| CRC length | L | 11 | | 6 | |
| # of PC bits | n_{PC} | 0 | | 3 | |
| # of row-weight PC | n_{PC}^{wm} | 0 | | 0 | 1 |
| bits | | | | | |

[symbol]

indicates data missing or illegible when filed

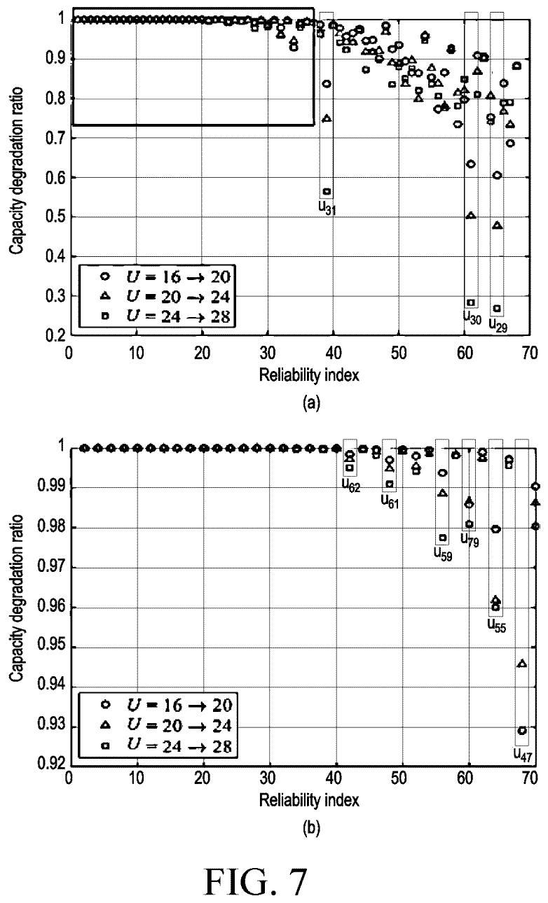

FIG. 7 illustrates a channel capacity degradation ratio for a reliability index according to the number (U) of punctured bits according to various embodiments of the present disclosure.

As described above, in the polar code split channel allocation step of the 5G-NR system, locations of the information bit/frozen bit/parity bit are determined. A frozen bit pattern (Q̅_{F}^{N}) is determined by pre-freezing (S₁), extra-freezing (S₂), and reliability-freezing (S₃). In the pre-freezing, capacity-0 bits in the u domain are determined by the puncturing pattern, and the bits are frozen (S₁=λₚ). However, the extra-freezing is performed for bits of which the capacities are not 0 but are determined to be sufficiently weak. That is, according to a reference for determining an extra-freezing set, the frozen bit pattern and the information set (Q̅_{I}^{N}) may be changed. At this time, the decoding performance also varies depending on a configuration of Q̅_{I}^{N}.

However, when the extra-freezing set is determined according to the number U of punctured bits, the existing extra-freezing set and the code rate are independent from each other when the number U of punctured bits is given. In the case of polar code in which the code is designed based on the quality of actually channel-polarized bit channels, a set of bits relatively weak at puncturing may vary depending on the number (A) of message bits or the code rate (A/E) For example, W(Q_{N-1-(K+1)}^{N})<(Q_{N-1-K}^{N}) is satisfied in the polar code that is not punctured (that is, the reliability of a bit having a reliability index K is higher than the reliability of a bit having a reliability index (K+1), but W(Q_{N-1-(K+1)}^{N})>W(Q_{N-1-K}^{N}) in the punctured polar code. Particularly, since the number of message bits is small when the code rate is low, relatively more weak bits by puncturing are included in the information set, thereby significantly deteriorating the decoding performance. Accordingly, an “additional extra-freezing (AEF) set” (notation: S₂^{A}) design rule considering the source bits is needed.

FIG. 7 illustrates a channel capacity degradation ratio by puncturing in N=128, BEC(0.5). According to [Equation 3] above, when the number of punctured bits is U=16, 20, 24, and 28, T in S₂={0, 1, . . . , T} corresponding to the extra-frozen bit set are 39, 41, 43, and 45 (the X axis is a reliability index i(∈[0: N−1]) and the Y axis is a channel capacity degradation ratio of a bit having an index of Q_{N-1-j}^{N}). In part (a) of FIG. 7, highlighted bits such as u₃₁, u₃₀, u₂₉ are bits always frozen by the extra-freezing rule of 5G-NR. However, when a channel capacity degradation degree in a low-code rate area is enlarged as illustrated in part (b) of FIG. 7, it may be identified that a relative channel capacity degradation ratio is not constant and a bit deviation is large. For example, a channel capacity degradation ratio of a bit having a reliability index of 34 (u₄₇, bit index of Q₉₄¹²⁸) is greatly larger than a channel capacity degradation ratio of a bit having a reliability index of 35(bit index of Q₉₃¹²⁸).

In summary, when only bits having indexes smaller than T are extra-frozen, weak bits having indexes larger than T are used as the information set at a relatively low code rate, and there is a limitation that it becomes a factor in performance deterioration.

The disclosure defines an additional extra-freezing (AEF) set which may vary depending on a puncturing degree and a message length (or a code rate) to improve a design method in order to secure the stable performance according to polar code puncturing and provides exclusion from selection of the information set. Alternatively, an extended extra-freezing (EEF) set including the extra-freezing set and the additional extra-freezing set as a union may be designed. This may be based on the design of an adaptive AEF set according to the message length (or code rate). For example, when A (K=A+L when the CRC bit is also included) is small, weak bits having a relatively low channel capacity may be additionally frozen. When A becomes larger, a bit excluded from the AEF set may be used again as the information bit by reducing the size of the AEF set. As described above, it is possible to improve the bit interleaved coded modulation (BICM) system performance of 5G-NR by adding a simple conditional statement about A as well as N, P. Particularly, it is possible to improve the performance at a low code rate through the design of the AEF (or EEF) set.

When the quality of split channels of the polar code is evaluated, a BER evaluation method using the channel capacity in the binary erasure channel and the density evolution method in the AWGN channel may be used. The channel capacity or the BER of the split channels of the punctured polar code are generally deteriorated. The decoding performance is prevented from deteriorating by determining that bits having bit indexes equal to or smaller than T are significantly deteriorated and thus extra-freezing the bits.

In the disclosure, it is possible to additionally define an AEF set S₂ ^{A} and extra-freeze members corresponding to an EEF set S₂^{E} (=S₂ ∪S₂ ^{A}) which is a union of the EF set S₂ and the AEF set S₂^{A}. S₂ ^{A} has a variable size according to A (or A/E). The size of the AEF set is the largest when A (or A/E) is smaller than a minimum threshold, and the size of the AEF set is 0 when A (or A/E) exceeds a maximum threshold. That is, when A increases to exceed the minimum threshold, the released bit may be used again as the information bit by reducing the size of the AEF set one by one.

In SC decoding of the polar code, a block error rate (BLER) is a sum of error rates of all information bits, and an upper bound is determined. Events in which the block error occurs may be expressed as a union as shown in [Equation 6] below corresponding to mutually exclusive events { [symbol] ᵢ} in which a first error occurs in an i^{th} bit.

$${ℬ}_{i} := \{ {u}_{0}^{N - 1} , r , {d}_{0}^{N - 1} \vert {\hat{u}}_{0}^{i - 1} = {u}_{0}^{i - 1} , {h}_{i} ( r , {\hat{u}}_{0}^{i - 1} ) \neq {u}_{i} ) \} \qquad [ Equation 6 ]$$

[symbol] ᵢ satisfies [symbol] ᵢ⊆{u₀^{N-1}, r, c₀^{N-}1|hᵢ(r, û₀ ⁱ⁻¹)≠uᵢ)}=: [symbol] ᵢ. That is, the BLER has [symbol] P( [symbol] ᵢ) as the upper bound. Accordingly, for the good performance, bits having a low BER obtained through density evolution evaluation may be selected and data thereon may be transmitted.

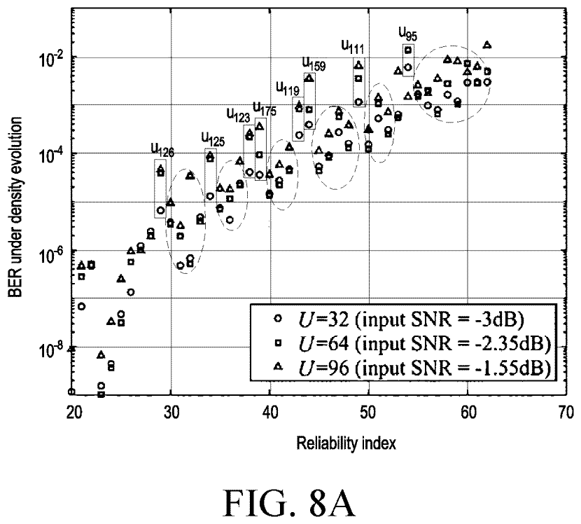

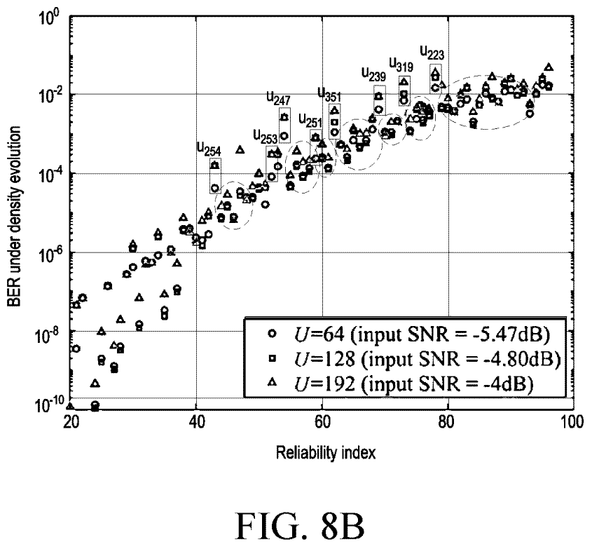

FIG. 8A illustrates a block error rate (BER) under density evolution according to a reliability index according to various embodiments of the present disclosure, and FIG. 8B illustrates a block error rate (BER) under density evolution according to a reliability index according to various embodiments of the present disclosure.

FIG. 8A is the result obtained by observing BERs of u bits according to the number of punctured bits through density evolution and shows a BER (A ∈ [20:62]) for each bit according to a reliability index in N=256, U ∈ {32, 64, 96}. At this time, an input SNR (of the channel) for each code parameter is determined that an SC decoding BLER at a code rate to be observed is near 10⁻³. Specifically, when U=32, 64, and 96, the input SNR is set to −3.00 dB, −2.35 dB, and −1.55 dB. When the reliability index increases, there is a trend of generally increasing the BER.

However, in the arrangement in the reverse order of the code sequence of 5G-NR (that is, in the order from the highest reliability to the lowest reliability), it can be known that specific bits having high BERs have smaller reliability indexes. Referring to FIG. 8A, (when the reliability index is j(∈[0: N−1]) a BER of a bit having an index of Q_{N-1-j}^{N} is frequently higher than BERs of bits having an index of {Q_{N-1-j}^{N}, . . . , Q_{N-1-(j+α)}} (α being a positive integer). For example, a BER of a bit of Q₁₂₈₋₁₋₂₉¹²⁸ (that is, u₁₂₆) having a reliability index of 29 is higher than BERs of bits of {Q₁₂₈₋₁₋₃₀¹²⁸, . . . , Q₁₂₈₋₁₋₃₄¹²⁸} having reliability indexes of 30 to 34. Such a tendency equally appears in N=512, which is illustrated in FIG. 8B.

FIG. 8B illustrates a BER under density evolution according to a reliability index in N=512, U ∈{64, 128, 192}, and it can be known that bits having relatively (significantly) higher BERs according to an increase in the reliability index are first included in [symbol] .

For a bit index i=(iₙ₋₁ . . . i₁i₀), location indexes corresponding to the most significant bit (MSB) and the least significant bit (LSB) are n−1 and 0. The number of 1 (or hamming weight of i) in the binary representation of i is expressed as d_{H} (i). Binary expansion of the index i in the polar code shows a polarization process of the source bit uᵢ in a multistage polarization process. The multistage polarization process is indicated in the order of bit indexes of the binary representation from n −1 to 0, and a value of 1 denotes experience of a channel upgrade and a value of 0 denotes experience of a downgrade. For example, in the case of) (1000), it means experience of the upgrade in a first polarization step and experience of three downgrades thereafter. Through analysis of the polarization process of the source bits, candidates to belong to the additional extra-freezing set are determined. To this end, the set S including location indexes corresponding to iₜ=0 is first defined as a “downgrade pattern.” For example, a bit having an index of 5=(0101) in [symbol] ₁₆, and thus has a downgrade pattern of (3,1). Further, a k-bit downgrade pattern means a location index sequence corresponding to k bits having iₜ=0 in the binary representation of i. At this time, bit indexes having the k-bit downgrade pattern are Σ_{i∈[0:n-1]\{j1, . . . , jk}}2ⁱ being location indexes of iₜ=0). For example, in [symbol] ₁₆, a 2-bit downgrade pattern is {(3,2), (3, 1), (3,0), (2, 1), (2,0), (1,0)} and bit indexes are 3, 5, 6, 9, 10, and 12.

In 5G-NR, bits having indexes smaller than N/4 are always extra-frozen even when the number of punctured bits is 0, which corresponds to extra-freezing of all bits corresponding to iₙ₋₁=iₙ₋₂=0. That is, (n−1) and (n−2) are always included in the downgrade pattern. Particularly, among all the 2-bit downgrade patterns, only (n−1, n−2) are included (that is, u_{N/4-1}). However, among all of

$$( \begin{matrix}n \\ 2\end{matrix} ) = \frac{n ( n + 1 )}{2}$$

2-bit downgrade patterns, there may be bits weak at puncturing as well as (n−1, n−2). For example, indexes and binary representation of bits weak at puncturing in FIG. 8A (N=256) and FIG. 8B (N=512) are as shown in [Table 2](N=256) and [Table 3](N=512).

TABLE 2

| Bit-index (i) | Binary expansion |
|---|---|
| 126 | 01111110 |
| 125 | 01111101 |
| 123 | 01111011 |
| 119 | 01110111 |
| 159 | 10011111 |
| 111 | 01101111 |
| 95 | 01011111 |
| 175 | 10101111 |

TABLE 3

| Bit-index (i) | Binary expansion |
|---|---|
| 254 | 011111110 |
| 253 | 011111101 |
| 251 | 011111011 |
| 247 | 011110111 |
| 239 | 011101111 |
| 223 | 011011111 |
| 191 | 010111111 |
| 319 | 100111111 |
| 351 | 101011111 |

They commonly experience at least one downgrade in first two polarization steps. For example, bits having index values of 126, 125, 123, 119, 111, and 95 shown in [Table 2] experience the downgrade in the first polarization step and additionally experience one downgrade in the remaining polarization steps. Bits having indexes of 159 and 175 in [Table 1] experience the downgrade in the second polarization step and additionally experience one downgrade in the following polarization step.

Similarly, in N=512, bits having index values of 254, 253, 251, 247, 239, 223, and 191 experience the downgrade in the first polarization step and additionally experience one downgrade in the remaining polarization steps. Bits having indexes of 319 and 351 in [Table 3] experience the downgrade in the second polarization step and additionally experience one downgrade in the following polarization step. These are bits of which 1) the downgrade pattern satisfies (n−1, t) t ∈ [n−2:0], and 2) the downgrade pattern satisfies (n−2, n−3) or (n−2, n−4).

The disclosure performs additional extra-freezing (AEF) conditionally for source bits having the more generalized 2-bit downgrade pattern in addition to consideration of only (n−1, n−2) in the 2-bit downgrade patterns. That is, in the disclosure, bits additionally extra-frozen (that is, AEF bits) may be determined according to several threshold conditions of the message length. Specifically, when the message length is smaller than a specific threshold, the AEF set includes all of (n+1) bits that satisfy the above two conditions. However, when the message length increases, the size of the AEF set is reduced, and when the message length is larger than the maximum threshold, the size of the AEF set becomes 0. This means that the released bit in the AEF set is used again as the information bit.

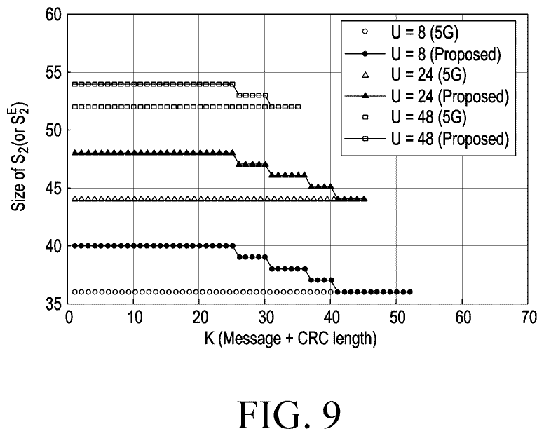

FIG. 9 illustrates comparison between sizes of sets of extra-frozen (EF) bits according to K (a sum of the number of message bits and the number of CRC bits) for various punctured polar codes according to various embodiments of the present disclosure.

FIG. 9 shows comparison between the sizes of the EF set (provided) determined according to the message length and the EF set (5G) determined without consideration of the message length defined in 5G-NR when N=128, U E {8, 28, 48}. The EF set S₂ defined in 5G-NR may be expressed as S₂=f(N,E). That is, regardless of the message length A, the size of the set is determined as a function of N and E (or U). On the other hand, the EF set in the disclosure is determined as a union of the EF set S₂ defined in 5G-NR and the additional extra-freezing set S₂^{A} according to A. The union is called an extended EF (EEF) set and can be expressed as S₂^{E}(=S₂∪S₂^{A}).

First, an index set [symbol] of bits particularly weak at puncturing is defined. The size of the set [symbol] is | [symbol] |=N_{w}, and may be expressed as W₁^{N}^{_{w}}=(w₁, w₂, . . . , w_{N}_{_{w}}) corresponding to an ordered sequence in the ascending order of reliability. The set [symbol] (or W₁^{N}^{_{w}}) may be determined in consideration of a channel state or an area (ex. A required SNR that achieves a BLER=0.1%) in which the code operates well. Alternatively, the set [symbol] (or W₁^{N}^{_{w}}) may be determined based on a downgrade pattern obtained through the polarization process. The AEF set S₂^{A} may be configured from the determined set [symbol] (or W₁^{N}^{_{w}}). In other words, S₂^{A} is determined as a subset or a sub-sequence of [symbol] (or W₁^{N}^{_{w}}), and the size of the subset is dependent on K (or A, A/E). S₂^{A}=set(W₁^{N}^{_{w}}) when K is smaller than a first threshold, and S₂^{A}=Ø when K is larger than a N_{w}_{^{th}} threshold. When K is small, all available weak bits are additionally extra-frozen. When the message length increases, relatively less weak bits are excluded from the additional extra-freezing set and used as bits for data transmission. That is, when the message length increases, the size of S₂ ^{A} is reduced one by one.

At this time, a threshold τ₁, τ₂, . . . , τ_{N}_{_{w}} (τ₁≤τ₂≤ . . . ≤τ_{N}_{_{w}}) for releasing each element is additionally defined, and the released bit is used again as the information bit to transmit data. When K is smaller than the threshold τ₁, S₂^{A}=set (W₁^{N}^{_{w}}). When K is larger than or equal to τ₁ and smaller than τ₂, S₂^{A} set (W₁^{N}^{_{w}}⁻¹). That is, as K increases, it exceeds the threshold, and each time this happens, the size of S₂^{A} is reduced by one. When K is larger than τ_{N}_{_{w}}, S₂^{A}=Ø(S₂ ^{E}=S₂). Through the AEF set provided in the disclosure, it is possible to improve the error rate performance in a low code rate area and also achieve the same performance as that of 5G-NR in a medium-high code rate area. N_{w}=8 may be determined when the set [symbol] including all weak bits of [Table 2] above is configured, and N_{w}=9 may be determined when the set [symbol] including all weak bits of [Table 3] is configured. [Table 4] below shows a method of designing the additional extra-freezing set S₂^{A}, based on [symbol] .

```
TABLE 4
  AEF set S₂^{A}, Weak-bit set [symbol]  (ordered sequence W₁^{N}^{_{w}}), Conventional EF set S₂, EEF
set S₂^{E} [symbol]
  E ≥ 3N/4,
  ${S}_{2} = \{ 0 , 1 , … , T \} where T = ⌈ \frac{3 N}{4} - \frac{E}{2} ⌉ - 1$ [symbol]
  -1. K < τ₁: S₂^{A} = W₁^{N}^{_{w}} = {w₁, w₂, ... , w_{N}_{_{w}}} [symbol]
  -2. τ₁ ≤ K < τ₂: S₂^{A} = W₁^{N}^{_{w}}⁻¹ = {w₁, w₂, ... , w_{N}_{_{w}}₋₁} [symbol]
  -3. τ₂ ≤ K < τ₃: S₂^{A} = W₁^{N}^{_{w}}⁻² = {w₁, w₂, ... , w_{N}_{_{w}}₋₂}
  .
  .
  . [symbol]
  -(N_{w}). τ_{N}_{_{w}}₋₁ ≤ K < τ_{N}_{_{w}}: S₂^{A} = W₁¹ = {w₁} [symbol]
  -(N_{w} + 1). τ_{N}_{_{w}} ≤ K: S₂^{A} = Ø
  S₂^{E} = S₂ ∪ S₂^{A} [symbol]
  E < 3N/4,
  ${S}_{2} = \{ 0 , 1 , … , T \} where T = ⌈ \frac{9 N}{16} - \frac{E}{4} ⌉ - 1$ [symbol]
  -1. S₂^{A} and S₂^{E} which are the same as those in a sub-process of [symbol]  are configured.
```

[Table 5] below shows an example of designing the additional extra-freezing set S₂^{A} when N_{w}=4. At this time, [symbol] (or the ordered sequence W₁⁴=(w₁, w₂, w₃, w₄) includes indexes of bits when the indexes are expressed in binary (a bit having the location of (n−1, n−3) as 0 and the remaining values of 1, a bit having the location of (n−1, n−4) as 0 and the remaining values of 1, a bit having the location of (n−2, n−3) as 0 and the remaining values of 1, and a bit having the location of (n−2, n−4) as 0 and the remaining values of 1). As an embodiment, S₂^{A} (or S₂^{E}) may be determined according to K based on W₁⁴. That is, the example of N_{w}=4 is an example of designing the additional extra-freezing set for bits that 1) experience one downgrade in the first or second step, 2) experience a total of two downgrades, and 3) all experience the upgrade in the remaining steps within first four polarization steps.

```
TABLE 5
  AEF set S₂^{A}, Weak-bit ordered sequence W₁⁴ = (w₁, w₂, w₃, w₄), Conventional EF set =
S₂, EEF set S₂^{E} = S₂ ∪ S₂^{A}
  (At this time, w₁ is a bit having a downgrade pattern of (n-1, n-3), w₂ is a bit having a
downgrade pattern of (n-1, n-4), w₃ is a bit having a downgrade pattern of (n-2, n-3), and
w₄ is a bit à having a downgrade pattern of (n-2, n-4),
${w}_{1} = \frac{6 N}{16} - 1 , {w}_{2} = \frac{7 N}{16} - 1 , {w}_{3} = \frac{10 N}{16} - 1 , {w}_{4} = \frac{11 N}{16} - 1 )$ [symbol]
  E ≥ 3N/4,
  ${S}_{2} = \{ 0 , 1 , … , T \} where T = ⌈ \frac{3 N}{4} - \frac{E}{2} ⌉ - 1$
  $- 1. K < {τ}_{1} : {S}_{2}^{A} = {W}_{1}^{4} = \{ \frac{6 N}{16} - 1 , \frac{7 N}{16} - 1 , \frac{10 N}{16} - 1 , \frac{11 N}{16} - 1 \}$
  $- 2. {τ}_{1} \leq K < {τ}_{2} : {S}_{2}^{A} = {W}_{1}^{3} = \{ \frac{6 N}{16} - 1 , \frac{7 N}{16} - 1 , \frac{10 N}{16} - 1 \}$
  $- 3. {τ}_{2} \leq K < {τ}_{3} : {S}_{2}^{A} = {W}_{1}^{2} = \{ \frac{6 N}{16} - 1 , \frac{7 N}{16} - 1 \}$
  $- 4. {τ}_{3} \leq K < {τ}_{4} : {S}_{2}^{A} = {W}_{1}^{1} = \{ \frac{6 N}{16} - 1 \}$ [symbol]
  -5. τ₄ ≤ K: S₂^{E} = S₂ (or S₂^{A} = Ø) [symbol]
  E < 3N/4,
  ${S}_{2} = \{ 0 , 1 , … , T \} where T = ⌈ \frac{9 N}{16} - \frac{E}{4} ⌉ - 1$ [symbol]
  -1. S₂^{A} which are the same as that in 1-3 of [symbol]  is configured.
```

When K (or R) is smaller than a first threshold τ₁, S₂^{A} may include all weak bits (4 bits). Bits having downgrade patterns (n−1, n−3), (n−1, n−4), (n−2, n−3), and (n−2, n−4) may be included (S₂^{A}=W₁⁴). When K (or R) is larger than or equal to the first threshold τ₁ and smaller than a second threshold τ₂, the size of S₂ ^{A} is reduced by one (S₂^{A}=W₁³). Specifically, the bit having the downgrade pattern (n−2, n−4) is excluded. When K (or R) is larger than or equal to the second threshold τ₂ and smaller than a third threshold τ₃, the size of S₂^{A} is reduced by one by excluding the bit having the downgrade pattern (n−2, n−3) (S₂^{A}=W₁²). When K (or R) is larger than or equal to the third threshold τ₃ and smaller than a fourth threshold τ₄ the size of S₂^{A} is reduced by one by excluding the bit having the downgrade pattern (n−1, n−4) (S₂^{A}=W₁¹). Last, when K (or R) is larger than the fourth threshold τ₄, S₂^{A} has the EF set which is the same as that in the prior art by excluding the bit having the downgrade pattern (n−1, n−3) (S₂^{A}=Ø or S₂^{E}=S₂). The first, second, third, and fourth thresholds τ₁, τ₂, τ₃, τ₄(τ₁≤τ₂≤τ₃≤τ₄) may be determined through various methods. For example, when thresholds for K are defined,

$${τ}_{2} = ⌊ \frac{N}{n - 3} ⌋ - 1 ,$$

τ₁=└T₂×0.795┘-1, τ₃=└T₂×1.1┘−1, and └τ₂×1.32 ┘−1 may be determined. Alternatively, thresholds for determining the AEF may be predefined for every code length, which is as shown in [Table 6].

TABLE 6

| | First | Second | Third | Fourth |
|---|---|---|---|---|
| | threshiod | threshold | threshold | threshold |
| N | (τ₁) | (τ₂) | (τ₃) | (τ₄) |
| 64 | 17 | 19 | 21 | 27 |
| 128 | 26 | 31 | 37 | 41 |
| 256 | 42 | 48 | 53 | 67 |
| 512 | 68 | 77 | 95 | 110 |
| 1024 | 112 | 144 | 153 | 187 |

Example of first, second, third, and fourth thresholds determined for AEF release (thresholds for K)

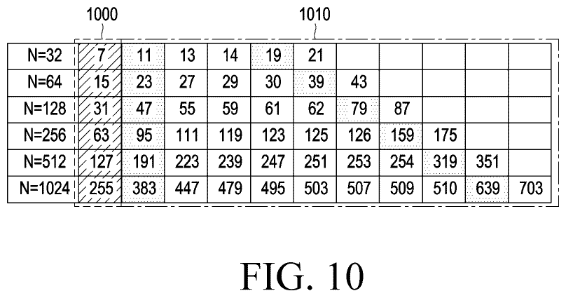

FIG. 10 illustrates bit indexes that additionally extra-frozen for each mother code length when bits of the polar codes are punctured according to various embodiments of the present disclosure.

In the disclosure, bits having the downgrade patterns (n−1, n−3) and (n−2, n−3) may be included in the weak bit set [symbol] . That is, in the configuration of [symbol] (or W₁^{N}^{_{w}}), the bits having the downgrade patterns (n−1, n−3) and (n−2, n−3) may be included with a minimum condition. In addition, bits having other downgrade patterns may be included according to circumstances. As an embodiment, the weak bit set [symbol] may be differently designed depending on a channel state and, for example, the weak bit set may be differently configured according to a target error rate range under density evolution.

More specifically, highlighted bit indexes in reference numeral 1010 of FIG. 10 indicate bit indexes determined as the additional extra-freezing set for each mother code-length (N) according to the disclosure. For example, in the case of N=32, 32=2⁵ and n=5, and it can be known that 11(01011) and 19(10011) corresponding to bit indexes having downgrade patterns (n−1, n−3) and (n−2, n−3), that is, (4,2) and (3,2) are determined as the additional extra-freezing set. In another example, in the case of N=64, 64=2⁶ and n=6, and it can be known that 23(01011) and 39(100111) corresponding to bit indexes having downgrade patterns (n−1, n−3) and (n−2, n−3), that is, (5.3) and (4.3) are determined as the additional extra-freezing set.

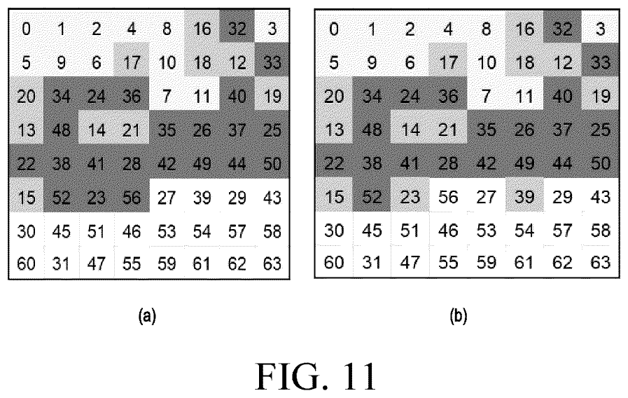

FIG. 11 illustrates a split channel allocation method for the EF set when light puncturing is applied according to various embodiments of the present disclosure.

FIG. 11 shows a split channel allocation method according to whether the message length is considered for the polar code corresponding to (N, A, U)=(64, 20, 12), in which E>3N/4(that is, 42>3*64/4) and the light puncturing is applied. As shown in part (a) of FIG. 11, when the message length is not considered, source bits corresponding to sub-block interleaved first U=12 indexes are frozen. That is, a pre-freezing set S₁ is S₁={0, 1, . . . , 11}. Since T=21 in an EF set S₂, S₂={0, 1, . . . , 21}. Accordingly, bits of S₁ ∪S₂={0, 1, . . . , 21} are first frozen, and first (N−K′−|S₁ ∪S₂|)=22 bits except for indexes included in S₁ ∪S₂ of Q₀⁶³ are additionally frozen (reliability-freezing). Accordingly, the information set Q̅ᵢ⁶⁴={27, 39, 29, 43, 30, 45, 51, 46, 53, 54, 57, 58, 60, 31, 47, 55, 59, 62, 63}.

As shown in part (b) of FIG. 11, when the message length is considered, frozen set members determined when the message length is not considered are all included. That is, all of the bits having indexes of {0, 1, . . . , 21} are frozen. At this time, additional extra-freezing set members by the additional conditional statement are determined as bit indexes having downgrade patterns (n−1, n−3) and (n−2, n−3), and in the case of N=64, 64=2⁶ and n=6, and {23(010111), 39(100111)}corresponding to bit indexes of (5,3) and (4,3) are determined as additional extra-freezing set members (S₂^{A}={23, 39}). Accordingly, since A=20, data is transmitted to the remaining 20 bits obtained by additionally freezing first N−K′-|S₁ ∪S₂|64-20−24=20 bits except for 24 indexes included in S₁∪S₂ from Q₀⁶³. That is, the information set Q̅_{I} ⁶⁴=Q̅_{I}⁶⁴={56, 27, 29, 43, 30, 45, 51, 46, 53, 54, 57, 58, 60, 31, 47, 55, 59, 61, 62, 63}.

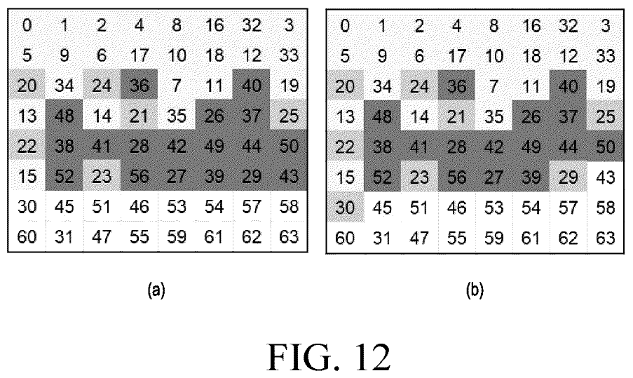

FIG. 12 illustrates a split channel allocation method for the EF set when heavy puncturing is applied according to various embodiments of the present disclosure.

FIG. 12 shows a split channel allocation method according to whether the message length is considered for the polar code corresponding to (N, A, U)=(64, 16, 24), in which E<3N/4 (that is, 40<3*64/4)) and the heavy puncturing is applied. As shown in part (a) of FIG. 12, when the message length is not considered, source bits corresponding to sub-block interleaved first U=24 indexes are frozen. Index set of the bits (that is, pre-freezing set S₁) is S₁={0, 1, . . . , 19, 32, 33, 34, 35}. In the case of extra-freezing,

$$T = ⌈ \frac{9 \times 64}{16} - \frac{40}{4} ⌉ - 1 = 25 ,$$

and thus indexes of S₂={0,1, . . . , 25} are extra-frozen (S₁≠S₂ in heavy puncturing). Accordingly, first N−K−|S₁ ∪S₂|=64−16−30=18 bits of Q₀⁶³ except for indexes of S₁ ∪S₂={0, . . . , 25, 32, 33, 34, 35} are reliability-frozen and data is transmitted to the remaining 16 bits. When the message length is not considered, elements of S₂ are not included in A=16, and thus the performance which is the same as that when extra-freezing is not performed is obtained. Unlike this, as shown in part (b) of FIG. 12, when the message length is considered, the EF set expanded from A=16 is S₂^{E}=S₂∪S₂^{A}={0,1, . . . , 25, 29, 30}, and thus data is transmitted to u₄₃ rather than to u₃₀.

As provided in the disclosure, when the additional extra-freezing set is applied in consideration of the message length, there is an effect of improving the decoding performance compared to the case where the additional extra-freezing set is not applied. More specifically, in the case of the decoding performance according to the modulation order and the decoding performance according to the code length, it is possible to acquire an additional performance gain by adaptively freezing relatively weak bits at a low coding rate through the application of the additional extra-freezing set in consideration of the message length.

Further, as provided in the disclosure, when the additional extra-freezing set is applied in consideration of the message length under successive cancellation list (SCL) decoding, there is an effect of improving the block error rate (BER) performance compared to the case where the additional extra-freezing set is not applied. In addition, as provided in the disclosure, even when the additional extra-freezing set is applied in consideration of the message length in a fading channel, there is an effect of improving the decoding performance.

A channel encoding device according to an embodiment of the disclosure may determine an additional extra-freezing (AEF) set S₂^{A} from an index [symbol] set of weak bits.

As an embodiment, the set [symbol] (or the ordered sequence W₁^{N}^{_{w}}) having the size N_{w} may be determined according to a channel parameter (for example, design of [symbol] in consideration of a BER for each bit considering puncturing in an SNR that achieves BLER=0.1%). Alternatively, the set [symbol] may be determined based on a 2-bit downgrade pattern obtained through a polarization process. For example, in the case of N_{w}=4, bits that 1) experience one downgrade in the first or second polarization step, 2) experience a total of two downgrades, and 3) experience the upgrade in the remaining steps. At this time, bits having downgrade patterns (n−1, n−3) and (n−2, n−3) may be included in [symbol] .

As an embodiment, a set S₂^{A} having a variable size may be determined according to K (or A, A/E) from the determined set [symbol] . Specifically, thresholds (τ₁, τ₂, . . . , τ_{N}_{_{w}}) to be released from the set S₂^{A} may be defined for every element (w₁, w₂, . . . , w_{N}_{_{w}}) of the set [symbol] (or the ordered sequence W₁^{N}^{_{w}}). When K is smaller than a minimum threshold τ₁, S₂^{A}=set (W₁^{N}^{_{w}}) is determined. Whenever K exceeds each threshold, the size of S₂^{A} is reduced by one, and when K exceeds a maximum threshold τ_{N}_{_{w}}, S₂^{A}=Ø, that is, the EF set which is the same as that in the case where the message length is not considered may be determined.

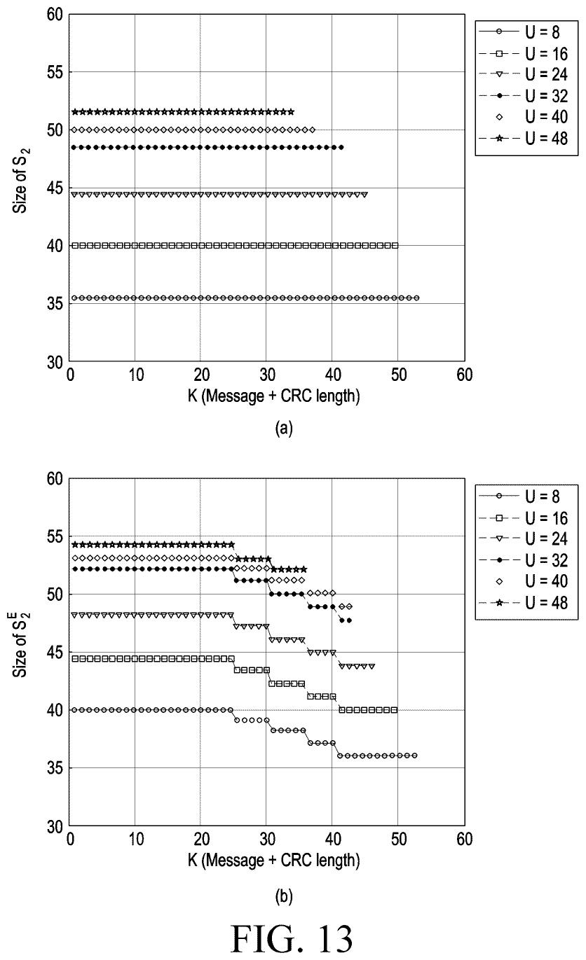

FIG. 13 illustrates sizes of sets of extra-freezing bits in puncturing of bits of the polar codes according to various embodiments of the present disclosure.

Part (a) of FIG. 13 shows an EF set determined without consideration of the message length according to the number of punctured bits (U=8, 16, 24, 32, 40, 48). That is, when is larger through the order relation between E(N−U) and 3N/4, all bits having indexes equal to smaller than

$$T = ⌈ \frac{3 N}{4} - \frac{E}{2} ⌉ - 1$$

are extra-frozen, and when E is smaller, all bits having indexes equal to or smaller than

$$T = ⌈ \frac{9 N}{16} - \frac{E}{4} ⌉ - 1$$

are extra-frozen.

Part (b) of FIG. 13 illustrates adaptive determination of the EF set, based on the number of message bits (or the code rate) according to the number of punctured bits (U=8, 16, 24, 32, 40, 48) according to the disclosure. The conventional extra-freezing set members may be maintained, and EF set members may be added according to the number of message bits (or code rate). When the number of message bits is smaller than the minimum threshold, all of the relatively weak bits may be included in the EF set. Whenever the number of message bits exceeds the threshold through an increase therein, the relatively weak bits may be released from the EF set one by one. When the number of message bits is larger than the maximum threshold, the EF set is the same as that determined without consideration of the message length.

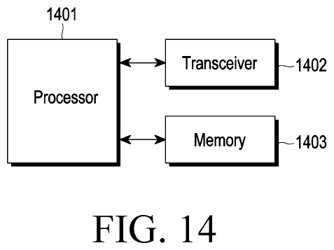

FIG. 14 illustrates a structure diagram illustrating the structure of an encoding device according to various embodiments of the present disclosure.

Referring to FIG. 14, the encoding device includes a processor 1401, a transceiver 1402, and memory 1403. The structure illustrated in the drawing corresponds to an embodiment, and the encoding device may further include units more than illustrated in FIG. 14.

The transceiver 1402 may transmit and receive signals to and from another electronic device (for example, a receiver). The memory 1403 may store at least one piece of information related to the transceiver 1402 and information transmitted and received through the transceiver 1402. Further, the memory 1403 may store sequence information for polar coding to which the disclosure is applied.

The processor 1401 may control the operation of the encoding device, and may overall control the encoding device to perform operations related to the encoding device in each of the embodiments described above.

According to an embodiment of the disclosure, the memory 1403 may store a basic program, an application program, and data such as configuration information for the operation of the electronic device. Particularly, the memory 1403 provides the stored data according to a request from the processor 1401. The memory 1403 may be configured by storage media such as ROM, RAM, hard disc, CD-ROM, and DVD, or a combination of the storage media. The number of memories 1403 may be plural. The processor 1401 may implement the above-described embodiments, based on a program for implementing the embodiments of the disclosure stored in the memory 1403 and may include at least one processor.

According to an embodiment of the disclosure, the processor 1401 may determine the length of a mother code, based on the length of at least one information bit to be transmitted and a target coding rate. The processor 1401 may determine at least one frozen bit to not transmit information among first bits included in an input source vector corresponding to the mother code, based on the length of at least one information bit to be transmitted. The processor 1401 may allocate at least one information bit to be transmitted to at least one second bit except for at least one determined frozen bit among the first bits included in the input source vector. The processor 1401 may generate a codeword by encoding the input source vector to which at least one information bit to be transmitted is allocated into a predetermined polar code.

As an embodiment, at least one frozen bit may be determined by puncturing. As an embodiment, at least one frozen bit may be determined by a parameter indicating a state of a channel for transmitting the transmission bit. As an embodiment, at least one frozen bit may be determined in consideration of bit indexes in binary representation indicating a polarization process for bits included in the input source vector corresponding to the mother code, and when the number of bit indexes in the binary representation is n, at least one frozen bit may include a bit having a bit index of “0” between (n−1, n−3) and (n−2,n−3).

As an embodiment, the number of at least one frozen bit may be determined by a first threshold and a second threshold for the length of the information bits to be transmitted, and the number of at least one frozen bit may be maximum when the length of the information bits to be transmitted is shorter than the first threshold and the number of at least one frozen bits may be minimum when the length of the information bits to be transmitted is longer than the second threshold.

As an embodiment, when the length of the bits to be transmitted is longer than or equal to the first threshold and equal to or shorter than the second threshold, the number of at least one frozen bits may be reduced to the number corresponding to an increase in the length of the information bits to be transmitted. As an embodiment, at least one frozen bit may include frozen bits determined by a pre-freezing set, an extra-freezing set, and a reliability freezing set. As an embodiment, the processor 1401 may allocate at least one information bit to be transmitted to at least one second bit in the order of bits having high channel reliability among at least one second bit.

In the above-described detailed embodiments of the disclosure, an element included in the disclosure is expressed in the singular or the plural according to presented detailed embodiments. However, the singular form or plural form is selected appropriately to the presented situation for the convenience of description, and the disclosure is not limited by elements expressed in the singular or the plural. Therefore, either an element expressed in the plural may also include a single element or an element expressed in the singular may also include multiple elements.

Although specific embodiments have been described in the detailed description of the disclosure, it will be apparent that various modifications and changes may be made thereto without departing from the scope of the disclosure. Therefore, the scope of the disclosure should not be defined as being limited to the embodiments set forth herein, but should be defined by the appended claims and equivalents thereof.

Although the present disclosure has been described with various embodiments, various changes and modifications may be suggested to one skilled in the art. It is intended that the present disclosure encompass such changes and modifications as fall within the scope of the appended claims.

What is claimed is:

1. A method for encoding a channel in a wireless communication system, the method comprising:
determining a length of a mother code based on a length of at least one information bit to be transmitted and a target code rate;
determining, based on the length of the at least one information bit, at least one frozen bit to not transmit information among first bits included in an input source vector corresponding to the mother code;
allocating the at least one information bit to at least one second bit except for the determined at least one frozen bit among the first bits included in the input source vector; and
generating a codeword by encoding, into a predetermined polar code, the input source vector to which the at least one information bit is allocated.

2. The method of claim 1, wherein the at least one frozen bit is determined by a puncturing operation.

3. The method of claim 1, wherein the at least one frozen bit is determined by a parameter indicating a state of a channel for transmitting the at least one information bit.

4. The method of claim 1, wherein the at least one frozen bit is determined considering bit indices in a binary representation indicating a polarization process for bits included in the input source vector corresponding to the mother code, and
wherein the at least one frozen bit includes a bit set to zero in at least one of a bit index (n−1, n−3) or a bit index (n−2, n−3) in case that a number of the bit indices is n.

5. The method of claim 1, wherein a number of at least one frozen bits is determined based on a first threshold and a second threshold for the length of the at least one information bit to be transmitted,
wherein the number of at least one frozen bit is identified as a maximum value in case that the length of the information bit to be transmitted is shorter than the first threshold, and
wherein the number of at least one frozen bit is identified as a minimum value in case that the length of the information bit to be transmitted is longer than the second threshold.

6. The method of claim 5, wherein, in case that the length of the bit to be transmitted is longer than or equal to the first threshold and equal to or shorter than the second threshold, the number of at least one frozen bit is reduced to a number corresponding to an increase in the length of the information bit to be transmitted.

7. The method of claim 1, wherein the at least one frozen bit includes frozen bits determined by a pre-freezing set, an extra-freezing set, and a reliability freezing set.

8. The method of claim 1, wherein allocating the at least one information bit to the at least one second bit comprises:
allocating the at least one information bit to the at least one second bit in an order of bits having high channel reliability, the bits corresponding to the at least one second bit.

9. An apparatus for encoding a channel in a wireless communication system, the apparatus comprising:
a transceiver; and
at least one processor operably coupled to the transceiver, the at least one processor configured to:
determine a length of a mother code, based on a length of at least one information bit to be transmitted and a target code rate;
determine, based on the length of the at least one information bit, at least one frozen bit to not transmit information among first bits included in an input source vector corresponding to the mother code;
allocate the at least one information bit to at least one second bit except for the determined at least one frozen bit among the first bits included in the input source vector; and
generate a codeword by encoding, into a predetermined polar code, the input source vector to which the at least one information bit is allocated.

10. The apparatus of claim 9, wherein the at least one frozen bit is determined by a puncturing operation.

11. The apparatus of claim 9, wherein the at least one frozen bit is determined by a parameter indicating a state of a channel for transmitting the at least one information bit.

12. The apparatus of claim 9, wherein the at least one frozen bit is determined considering bit indices in a binary representation indicating a polarization process for bits included in the input source vector corresponding to the mother code, and
wherein the at least one frozen bit includes a bit set to zero in at least one of a bit index (n−1, n−3) or a bit index (n−2, n−3) in case that a number of the bit indices is n.

13. The apparatus of claim 9, wherein a number of at least one frozen bits is determined based on a first threshold and a second threshold for the length of the at least one information bit to be transmitted,
wherein the number of at least one frozen bit is identified as a maximum value in case that the length of the information bit to be transmitted is shorter than the first threshold, and
wherein the number of at least one frozen bit is identified as a minimum value in case that the length of the information bit to be transmitted is longer than the second threshold.

14. The apparatus of claim 13, wherein, in case that the length of the bit to be transmitted is longer than or equal to the first threshold and equal to or shorter than the second threshold, the number of at least one frozen bit is reduced to a number corresponding to an increase in the length of the information bit to be transmitted.

15. The apparatus of claim 9, wherein the at least one frozen bit includes frozen bits determined by a pre-freezing set, an extra-freezing set, and a reliability freezing set.

16. The apparatus of claim 9, wherein the at least one processor is configured to:
allocate the at least one information bit to the at least one second bit in an order of bits having high reliability, the bits corresponding to the at least one second bit.
